(19) United States
(12) Patent Application Publication
(10) Pub. No.: US 2026/0045690 A1
(43) Pub. Date: Feb. 12, 2026

(54) A PHASE MULTIPLICATION CIRCUIT

(71) Applicant: INTERNATIONAL ELECTRIC COMPANY LIMITED, Derby (GB)

(72) Inventor: Ian CASH, Derby (GB)

(73) Assignee: INTERNATIONAL ELECTRIC COMPANY LIMITED, Derby (GB)

(21) Appl. No.: 19/100,264

(22) PCT Filed: Aug. 2, 2023
(86) PCT No.: PCT/GB2023/052052

§ 371 Date: Jan. 31, 2025

(30) Foreign Application Priority Data
Aug. 2, 2022 (GB) 2211254.4

(51) Int. Cl. H01Q 3/38; H03K 5/00

(52) U.S. Cl. CPC H01Q 3/38; H03K 5/00

(57) ABSTRACT

A phase multiplication circuit comprising a phase multiplier comprising a network of linear passive directional couplers acting on the phase difference between a differential signal pair, +θ and −θ, together with a third signal, ρ, which is the average phase of the differential pair and outputting one or more signals with magnitude proportional to the input signals and with a phase shift proportional to the input phase difference.

This invention relates to circuits for phase gain, i.e., phase multiplication, referred to as a phase multiplication circuit. It in particular relates to a passive circuit for achieving phase gain of signals. It also relates to a phased array that includes such circuits.

Phase multipliers take an input signal and produce an output signal where the phase of the output signal is an integer or non-integer multiple of the input signal. They have a wide range of utility but one proposed application is within a phased array. In a typical arrangement of a phased array, phase multipliers are not used and instead active phase shifters are associated with each element (or between adjacent elements in the case of a serial configuration). The phase shifters can either be controlled independently or (more typically for uniformly spaced planar and linear arrays) varied such that the phase difference between each adjacent pair of elements is essentially the same for each dimensional axis. Thus, the wavefront emitted from the phased array can be steered in one or two dimensions (i.e., azimuth, elevation) with a simple relationship between steering angle and the common phase difference between adjacent elements in each axis. The requirement for multiple phase shifters and control circuitry adds to the bulk and complexity of the phased array.

U.S. Pat. No. 4,408,205A discloses an alternative passive array driving technique for one-dimensional phased arrays in which the multiple active phase shifters could, in-principle, be replaced by a passive component known as a Rotman lens. This essentially 2D structure can be implemented as a waveguide, printed circuit, or by other techniques. Power may be applied to the lens at one port and beam dispersion will affect power splitting across other ports of the lens. These other ports would then drive the elements of the phased array. A beam can be steered by switching the power to different input ports of the lens, providing a rudimentary phase multiplication circuit. However, such a lens cannot produce a continuous, smooth sweep of beam direction emitted from a connected phased array antenna. Active components are also needed to perform the switching with the number of active components is principally determined by the number of switched inputs to the lens but also includes controlled variable passive components. Active components are expensive when compared with passive components and of course also consume power.

Patent U.S. Ser. No. 10/897,082B1 teaches an alternative arrangement which reduces the number of phase-shifters, where a phased array having M rows and N columns requires M+N phase shifters, rather than the more usual case of M×N.

For a phase difference of α between adjacent rows and β between adjacent columns, this patent claims that (for example) a Wilkinson power combiner can be used at each element to generate an average phase of [α+β]/2.

However, this comes at a cost of significant variable magnitude, requiring the addition of a variable gain amplifier at each element, as conceded in the patent. If +θ is exchanged for α and −θ for β, then it is evident by inspection that the sum port Σ has the mid-point (average) phase of α and β. As the difference between α and β varies from 0° to 90° (θ=+/−45° as depicted), Σ reduces in magnitude from 100% to 70.7% (1/√2), which is a 50% (3 dB) power drop. As this α/β difference increases further to 180°, the power in Σ reduces to zero. This loss in power (balanced by gain in power at the difference port Δ in a 4-port coupler) is non-recoverable in the Wilkinson power combiner; rather, it is dissipated through a local parallel resistance between α and β inputs, which is necessary to maintain impedance matching.

It is an object of the invention to provide a phase multiplication circuit that is suitable for use in a one dimension or two-dimensional phased array or in a range of other devices as an alternative to the use of active phase shifters.

According to a first aspect the invention provides a phase multiplication circuit comprising at least one phase multiplier comprising a network of linear passive directional couplers acting on an input phase difference between input signals which are an input differential signal pair, +θ and −θ, together with a third signal, ρ, which is the average phase of the input differential signal pair, and outputting one or more output signals with magnitude proportional to the input signals and with a phase shift proportional to the input phase difference.

The phase multiplier may comprise a pair of input ports, each receiving a respective one of the input differential signal pair +θ and −θ, and a third input port which receives the third signal and at least one pair of output ports at which an output differential pair of signals, which are each a multiple of a respective input signal, are output., The network of linear passive directional couplers may connect the pair of input ports of the phase multiplier to the at least one pair of output ports, each linear passive directional coupler may be a directional four-port coupler comprising a passive four-port device capable of performing analogue vector sum and difference operation.

Each directional four-port coupler of the phase multiplication circuit may comprise a bi-directional device, such that the phase multiplication circuit can be driven in reverse to transfer signals applied at the phase multiplier output ports back to the phase multiplier input ports with a phase division function.

The phase multiplication circuit may comprise only one-dimensional circuit elements, such as the linear passive directional couplers along with transmission lines that connect selected ones of input coupler ports and/or output coupler ports to ports of other linear passive directional couplers to form a network.

The term one-dimensional used here refers to the network being made up of components such as waveguides where the cross-sectional dimensions are small with respect to the wavelength.

The phase multiplication circuit may be entirely formed of passive components thereby forming a passive phase multiplication circuit, or may include one or more stages of phase multiplication that are passive along with a limited amount of active componentry.

The multiplication of the phase multiplication circuit may be achieved solely by feeding signals into and out of the input coupler ports and output coupler ports of the network of linear passive directional couplers, each input coupler ports and output coupler port being connected either to a phase multiplication circuit input, a phase multiplication circuit output or to an input coupler port or an output coupler po port of another linear passive directional coupler. Where two linear passive directional couplers are connected they may be connected by a one-dimensional interconnect with no other active or passive components therebetween.

The phase multiplier may output at least three signals with magnitudes proportional to the input magnitudes of +θ, −θ and ρ, but with common positive (or negative) phase shift as a multiple of θ. This provides a phase multiplication circuit which is suitable for cascading with similar circuits to achieve an overall phase shift which is a greater multiple of θ than one phase multiplication circuit acting alone.

The phase multiplication circuit may comprise a reciprocal network whereby, via reciprocity of its linear, passive components, the phase multiplication circuit can function in the reverse sense (i.e., operate bidirectionally), where outputs are swapped for inputs (and vice-versa).

The linear passive directional couplers may be suitable for operation over a narrow frequency band, such as frequencies suitable for use in a power transfer application, or over a wide frequency band which may be useful for enabling digital communications “power plus data” services. An example of a linear passive directional coupler that can be used over a wide band is a Lange coupler suitable for use over a wide RF (Radio Frequency) band.

The phase multiplication circuit may be operable over acoustic, for example ultrasonic, or Radio frequencies including microwave frequencies by appropriate selection of components to form the network.

It is often assumed that a linear passive directional coupler is inherently an electromagnetic device since the majority of commercial examples have either coaxial or electromagnetic waveguide ports. Nevertheless, acoustic directional couplers are known and may be utilised in the phase multiplication circuit of the invention. These are four port couplers and behave much like a conventional linear passive directional couplers, except that their ports are acoustic waveguides that conduct pressure waves in a medium, typically air.

The directional couplers may comprise devices realised using PCB (Printed Circuit Board) techniques.

The passive phase multiplication circuit may be formed using standard PCB fabrication techniques such as etched PCB processes.

In addition to the directional couplers, the circuit may include a plurality of resistors, whereby the one or more ports of one of more of the directional couplers is connected to a ground through a resistor.

The phase multiplier may have a fixed gain or multiplication factor for a defined frequency or over defined frequency band of radiation. They may be functional in the RF range for example or other ranges.

The passive phase multiplication circuit may include an input stage which is adapted to supply the input differential signal pair (a pair of anti-phase vector signals) +θ and −θ and a reference input at 0 degrees which are fed to the input of the phase multiplier.

The input stage may comprise variable phase sources for each of the +θ and −θ signals and for the 0 degrees reference signal. The input stage may include at least one signal generator and at least one phase shifter for each of the +θ and −θ signals.

The phase multiplication circuit may comprise a plurality of phase multipliers that are connected in a tree-like network of branches, each branch having a root node and multiple leaf nodes, the phase multipliers in each branch acting on the input phase difference provided at the input root nodes and distribute this input phase difference or multiple thereof across multiple adjacent pairs of leaf nodes. Alternatively, this tree-like network may operate in the reverse sense, receiving multiple signals with similar phase difference between adjacent “leaf” inputs, and combining these signals into a differential output pair (with-or-without mid-phase reference) at the “root” outputs. Each phase multiplier may comprise in one arrangement three or more phase multiplier sub-circuits, each configured as a network of passive linear couplers, acting on the phase difference between an input differential signal pair together with a third signal, ρ, which is the average phase of the input differential pair and outputting one or more signals with magnitude proportional to the input signals and with a phase shift proportional to the input phase difference. The phase multiplier sub-circuits may be cascaded whereby the output signals of a first of the phase multiplier sub-circuit are fed as inputs to a second, and the output signals of the second phase multiplier sub-circuit are fed as inputs to a third of the phase multiplier sub-circuits, the output of the third phase multiplier sub-circuit having a phase shift that is the sum of the phase shifts of all three phase multiplier sub-circuits.

Each of the cascaded phase multiplication sub-circuits may provide a phase shift which is a non-integer multiple of 0 or with the overall three cascade circuit providing an integer phase offset through addition of the offset of each stage. For example, each cascaded stage may add 0.33 θ of phase shift, so that a cascade of three stages gives +1θ phase shift, a cascade of six stages would give +2θ of phase shift, etc.

A plurality of phase multipliers, each of which may be a cascade of sub-circuits, may be connected in a tree-like network of branches, each branch having a root node and multiple leaf nodes, the phase multipliers in each branch acting on the initial phase difference provided at the input root nodes and distribute this phase difference or multiple thereof across multiple adjacent pairs of leaf nodes. Alternatively, this tree-like network may operate in the reverse sense, receiving multiple signals with similar phase difference between adjacent “leaf” inputs, and combining these signals into a differential output pair (with-or-without mid-phase reference) at the “root” outputs.

Each of the phase multipliers may comprise a network of multiple linear passive directional couplers that achieve phase gain by one of (or a combination of) three means:
1) attenuation of either orthogonal component
2) skewing, such that the angle between components is no-longer orthogonal
3) rotation of both orthogonal components. Where the phase multiplication circuit has multiple cascaded levels of phase multiplication the circuit can include more than one of these network configurations.

Where a first configuration is used, the phase multiplication circuit may be configured to provide a resolving means to resolve an input differential signal pair +θ, −θ, that follow a circular path when plotted on a Nyquist plot into orthogonal Σ and Δ components, an attenuation means to attenuate one of the Σ and Δ components, a recombining means recombine the attenuated and unattenuated component to turn them back into an intermediate differential pair of signals +θ′ and −θ′ that follow an elliptical path when plotted on a Nyquist plot, and a subtraction means to subtract a fixed phase offset from outputs +θ′ and −θ′, such that they have an approximate circular trajectory when plotted on a Nyquist plot.

The attenuation and fixed phase offset may be selected such that the approximate circular trajectory closely matches the ideal circular plot that would be achieved if the multiplication was perfect. For example, the A current/voltage signal may be attenuated to give Δ′, e.g., by half (−6 dB power attenuation).

The network may include an unequal-split directional coupler as a suitable means to provide attenuation and an equal split directional coupler that resolves the orthogonal components. The network may include a directional coupler that recombines the attenuated and unattenuated component to turn them back into the intermediate differential pair of signals. Further couplers may be configured to receive the intermediate pair of signals along with the reference fixed phase offset ρ to produce an output pair of signals +θ′ and −θ′. The fixed reference phase offset may comprise a fixed phase of 0 degrees.

Where a second configuration is used the phase multiplication circuit may be configured to define a resolving means to resolve an input differential signal pair +θ, −θ, into Σ and Δ components. The phase multiplication circuit may include a skewing means to apply a skew to the angle between Σ and Δ away from 90°, recombining means to recombine the skewed Σ and Δ signals to turn them back into an intermediate differential signal pair, and subtraction means to subtract a fixed phase offset from outputs +θ′ and −θ′, such that they have an approximate circular trajectory when plotted on a Nyquist plot

Where the second configuration is used, the phase multiplication circuit may comprise a first coupler that resolves the input differential signal pair +θ, −θ, into Σ and Δ components. The phase multiplication circuit may include a fixed phase shift that skews the angle between Σ and Δ away from 90°. Another coupler may be provided that recombines the skewed Σ and Δ signals to turn them back into an intermediate differential signal pair having an elliptical trajectory. Further couplers may be configured to receive the intermediate differential signal pair along with the reference fixed phase offset ρ to produce a pair of output signals +θ′ and −θ′. This may be implemented by attenuating one intermediate signal, adding a smaller fixed offset to this, subtracting a larger fixed offset from the second intermediate signal, so-as to re-circularise and align the output phase trajectories (+θ′ and −θ′) to achieve phase gain.

Where a third network configuration is used the phase multiplication circuit may comprise a multi-step means approximating an ideal rotation (as a fraction of θ) of resolved axial components, as the individual inputs of the differential pair +θ, —θ, each sweep through 90°.

For example, the ideal rotation may be +30° (i.e., 0.33 θ), where a significant proportion of +θ is initially split-off via a 4:1 power-splitting directional coupler. This may leave a remainder with equal magnitude to −θ. The remainder may then be combined with −θ and resolved via a 1:1 directional coupler into skewed axial components F and A, as part of a first step of approximation. This combination is discussed in more detail in relation to the second configuration.

The first step of approximation may further include the third input, mid-phase reference p, being split (via a 2:1 directional coupler) to then act twice on the remainder:
firstly as an offset subtraction to provide +θ′ (such that when shown on a Nyquist plot, a straight line drawn through the start and end points of its phase trajectory pass through the origin); and
secondly to further split equally, via a 1:1 directional coupler acting on +θ′ and the second proportion of ρ, into +θ′ and +θ″′ signals with +/− offsets (such that when shown on a Nyquist plot, +θ″ and +θ″′ have phase trajectories which end and start, respectively, at the origin).

A second step of approximation may involve combining +θ″ with Σ and combining +θ″′ with Δ, via 1:1 directional couplers, to give new axial components Σ′ and Δ′. These new axial components may then be combined together, via a 1:1 directional coupler, to give differential output pair, +θ″″ and −θ″″. This differential output pair +θ″″ and −θ″″ is shifted by 0.33 θ, in the same sense, with respect to inputs +θ and −θ respectively.

Lastly, the otherwise wasted signal produced as the “sum” output resulting from the initial +θ′ offset subtraction (i.e., where +θ′ has offset added) may be attenuated. This may be implemented via a 13:1 directional coupler. The attenuated signal may then be combined, via 2-off 1:1 directional couplers, with two other “waste” signals ρ′ and ρ″ created as a by-product of Σ′ and Δ′. This gives an output ρ″″ having 0.33 θ phase shift with respect to fixed-phase input ρ.

According to a second aspect, the invention provides a phased array comprising a phase multiplication circuit according to the first aspect, and a set of transmitting or receiving antennas or acoustic element each element connected to a respective one of the output ports of the phase multiplication circuit.

The phase multiplication circuit and elements of the phased array may be linearly arranged as one row of antennae, to form a linear phased array, or as a two-dimensional array in which the elements are arranged in a grid to define rows and columns of elements.

The acoustic elements may comprise horns matching the acoustic impedance of free air (or liquid) to the pressure wave channels of the waveguides and acoustic directional couplers forming the phase multiplier. The choice of element will depend on the frequency at which the phased array is to transmit or receive signals. This will also dictate the choice of components used to form the phase multiplying circuit.

The phased array may include two active phase shifters to generate the two antiphase differential signals with respect to the common fixed phase reference. For example, the active phase shifter may be configured to vary the phase difference between the generated anti-phase signals may be varied between 0° and 180°. This will in turn control a steering angle of the antennae as it will vary the phase difference between signals output from adjacent array output ports in the phased array.

The phased array may include a controller which controls the phase shifts set by the two active phase shifters. Where the required passive circuitry may be implemented as a copper pattern in the printed circuit. Cost is then determined principally by the area of PCB material required, not by the intricacy of the copper pattern produced.

The phased array may comprise only passive componentry that is operable in the electromagnetic or acoustic domain to generate the required output signals for each antenna or acoustic element of the phased array, with the only active parts of the phased array being the active phase shifter(s) and any power amplifier(s) or acoustic transducers at the very input to the circuit.

The phase multiplying circuit may provide a linear cascade of phase multipliers, or a parallel configuration of phase multipliers, or a tree like configuration of phase multipliers, or a combination as required. The tree like configuration may comprise a plurality of branches, each connected to a root node and feeding one or more leaf nodes with one or more phase multipliers in each branch of the tree.

The phased array may be operable to provide a range of beam directions or beam patterns from a single fixed frequency (or narrow band) source, with the output signals having a fixed frequency over the range of different beam patterns. Alternatively, it may be operable to provide a range of beam directions or beam patterns from a source that may vary over a wide frequency band using appropriate couplers such as Lange couplers.

The phased array may comprise a linear transmitting or receiving phased array, where the antenna elements (or acoustic transducers) are connected to the “leaf” nodes of a phase multiplication circuit of claim 9, and either this transmitting phased array is steered by the phase difference signals provided at the root-node, or this receiving phased array provides power-combination and received signal direction information via the signals output at the root node.

Alternatively the phased array may comprise a two-dimensional transmitting (or receiving) phased array system where the antenna elements (or acoustic transducers) are connected to the “leaf” nodes of a phase multiplication circuit of the first aspect of the invention, the phased array having x by y elements and comprising 3×3 or-more inputs (3×3 or-more outputs) at the “root” nodes connected to a first layer of 3-off (or more) tree-like networks, each with x number of “leaf” nodes, which then connect to a second layer of x number of tree-like networks, each with y number of “leaf” nodes. Thus, there are x by y leaf nodes connected to the x by y elements in the phased array.

In a further alternative, the phased array may comprise a two-dimensional steerable phased array system of arbitrary size, comprising two-or-more sub-arrays arranged as planar, cylindrical, or other geometry.

According to a third aspect the invention provides a method of achieving phase multiplication of an input differential signal pair using a network of passive components, the method comprising:
feeding the pair of signals into a network of passive components together with a zero-degree reference signal, the network being configured to perform linear vector arithmetic on the input differential signal pair that includes at least one of the following steps;
(i) Resolving the pair of signals into their real and imaginary components and attenuating either the real or imaginary or both real and imaginary axial signal components;
(ii) Resolving the pair of signals into their real and imaginary components and skewing of either the real or imaginary or both of the axial signal components; and
(iii) rotation of both axial components of the pair of signals.

Where the method includes step (i), the step (i) may comprise the sub steps of resolving the input differential signal pair +θ, −θ, that follow a circular path when plotted on a Nyquist plot into orthogonal Σ and Δ components, attenuating one of the Σ and Δ components, recombining the attenuated and unattenuated component to turn them back into an intermediate differential signal pair +θ′ and −θ′ that follow an elliptical path when plotted on a Nyquist plot, and subtracting a fixed phase offset from outputs +θ′ and −θ′, such that they again an approximate circular trajectory when plotted on a Nyquist plot.

The method may comprise applying an attenuation and fixed phase offset such that the approximate circular trajectory closely matches the ideal circular plot that would be achieved if the multiplication was perfect.

Where the method includes step (ii), the step (ii) may comprise the sub-steps of resolving the input differential signal pair +θ, −θ, into Σ and Δ components, applying a skew to the angle between Σ and Δ away from 90°, recombining the skewed Σ and Δ signals to turn them back into an intermediate differential signal pair, attenuate one of the intermediate signals and adding a fixed phase offset from the other intermediate signal, such that they have an approximate circular trajectory when plotted on a Nyquist plot.

Where the method includes step (iii) this step may involve the sub-steps of:
approximating an ideal rotation (as a fraction of 0) of resolved axial components, as the individual inputs of the differential pair +θ, −θ, each sweep through 90°, wherein a significant proportion of +θ is initially split-off via a power-splitting directional coupler to leave a remainder with equal magnitude to −θ;
combining the remainder with −θ and resolving via a directional coupler into skewed axial components Σ and Δ;
splitting the third input, mid-phase reference ρ, via a directional coupler to then act twice on the remainder, firstly as an offset subtraction to provide +θ′, secondly to further split equally into +θ″ and +θ″′ signals with +/− offsets;
combining +θ″ with Σ and combining +θ″′ with Δ, via directional couplers, to give new axial components Σ′ and Δ′; and
combining the new axial components, via a directional coupler, to give differential output pair, +θ″″ and −θ″″ shifted in the same sense with respect to inputs +θ and −θ respectively.

Step (iii) may further include an additional sub-step wherein the otherwise wasted signal produced as the “sum” output resulting from the initial +θ′ offset is attenuated. The attenuated signal may then be combined with two other “waste” signals ρ′ and ρ″ created as a by-product of Σ′ and Δ′ to give an output ρ″″ (having a phase shift with respect to fixed-phase input φ.

For example, the ideal rotation may be +30° (i.e., 0.33 θ), where a significant proportion of +θ is initially split-off via a 4:1 power-splitting directional coupler. This may leave a remainder with equal magnitude to −θ. The remainder may then be combined with −θ and resolved via a 1:1 directional coupler into skewed axial components Σ and Δ, as part of a first step of approximation. This combination is discussed in more detail in relation to the second configuration.

The first step of approximation may further include the third input, mid-phase reference ρ, being split (via a 2:1 directional coupler) to then act twice on the remainder:
firstly as an offset subtraction to provide +θ′ (such that when shown on a Nyquist plot, a straight line drawn through the start and end points of its phase trajectory pass through the origin); and
secondly to further split equally, via a 1:1 directional coupler acting on +θ′ and the second proportion of ρ, into +θ″ and +θ″′ signals with +/− offsets (such that when shown on a Nyquist plot, +θ″ and +θ″′ have phase trajectories which end and start, respectively, at the origin).

A second step of approximation may involve combining +θ″ with Σ and combining +θ″′ with Δ, via a 1:1 directional couplers, to give new axial components Σ′ and Δ′. These new axial components may then be combined together, via a 1:1 directional coupler, to give differential output pair, +θ″″ and −θ″″. This differential output pair +θ″″ and −θ′′ is shifted by 0.33 θ, in the same sense, with respect to inputs +θ and −θ respectively.

Lastly, the otherwise wasted signal produced as the “sum” output resulting from the initial +θ′ offset subtraction (i.e., where +θ′ has offset added) may be attenuated. This may be implemented via a 13:1 directional coupler. The attenuated signal may then be combined, via 2-off 1:1 directional couplers, with two other “waste” signals ρ′ and ρ″ created as a by-product of Σ′ and Δ′. This gives an output ρ′′ having 0.33 θ phase shift with respect to fixed-phase input ρ.

There will now be described by way of example several embodiments of the present invention with reference to and as illustrated in the accompanying drawings of which:

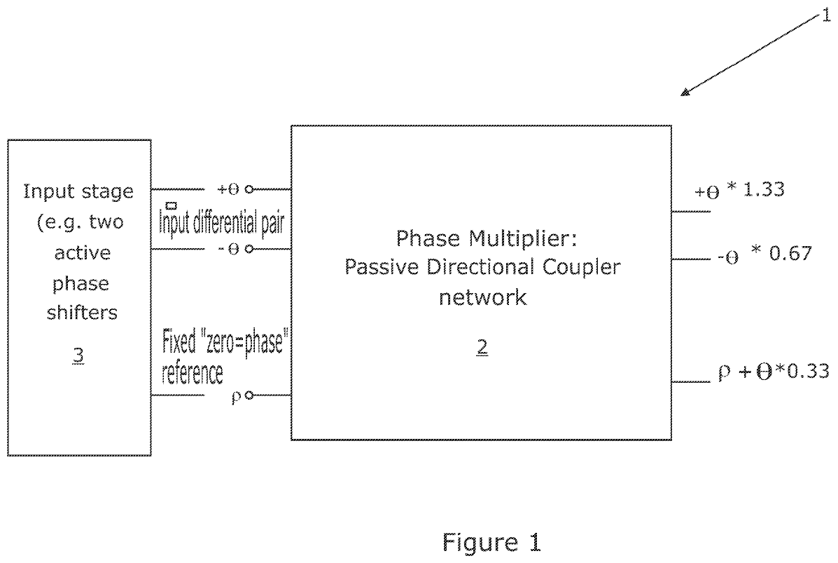

FIG. 1 is a block diagram showing the main functional parts of a passive phase multiplication circuit including a phase multiplier fed by an appropriate input stage in accordance with an aspect of the invention;

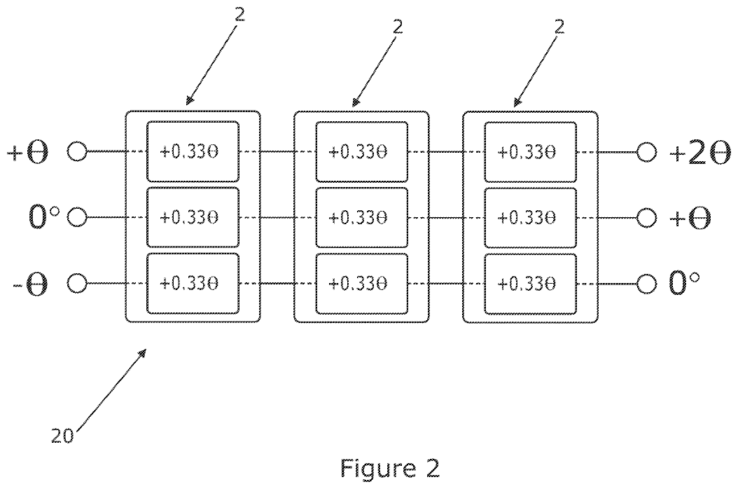

FIG. 2 is a block diagram showing a further embodiment of a phase multiplication circuit formed by cascading three of the phase multiplier circuits of FIG. 1;

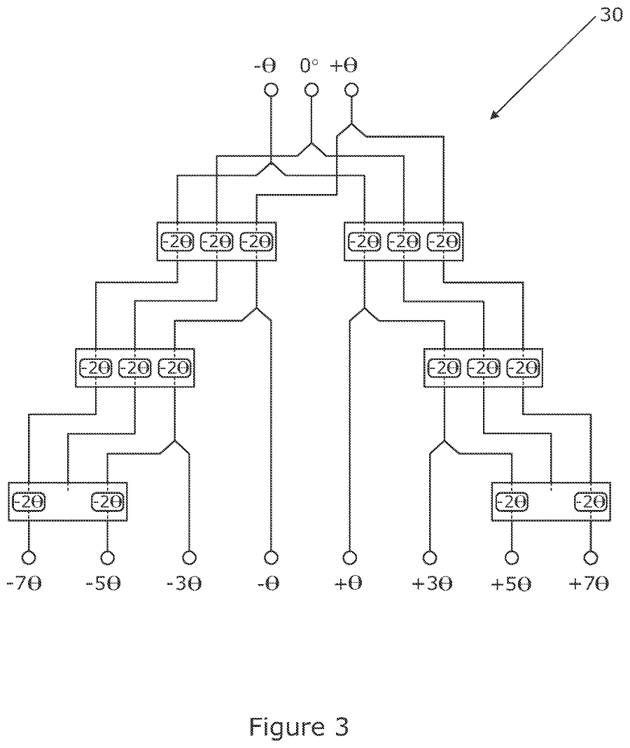

FIG. 3 shows how six pairs of the circuits of FIG. 2, each pair giving a phase shift of +2 θ and −2 θ can be combined to provide further phase multiplier outputs;

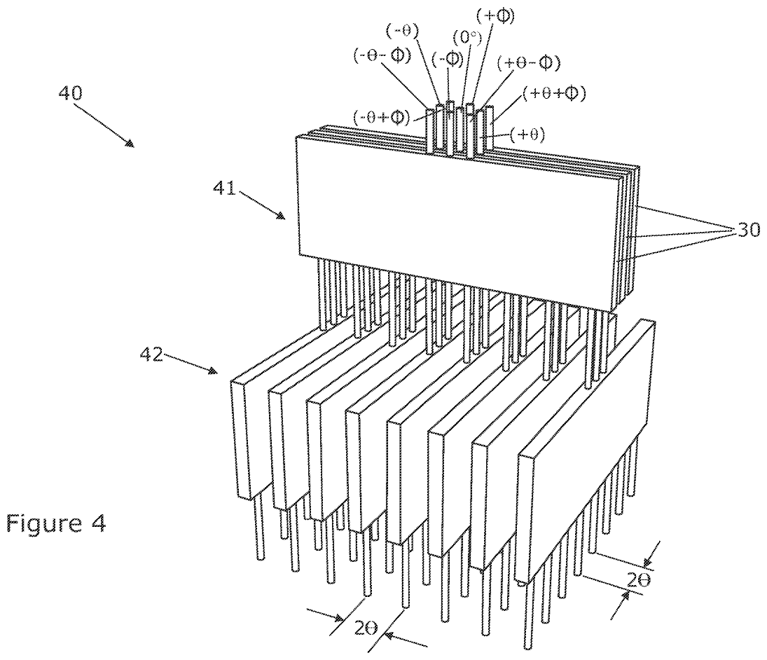

FIG. 4 is an overview of a two-dimensional phase multiplication circuit that can be formed using the circuits of FIGS. 1 to 3 as building blocks;

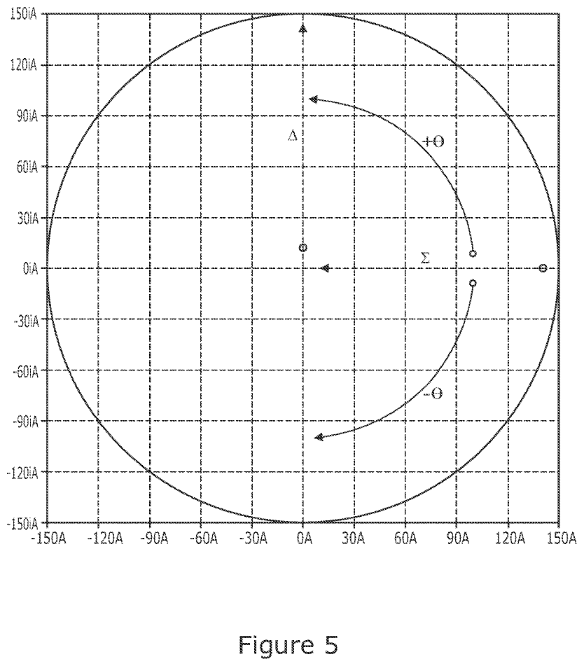

FIGS. 5 to 15 are a Nyquist plots which each show the real and imaginary parts of various signals within a phase multiplication circuit in accordance with the invention constructed according to one of three different network topologies;

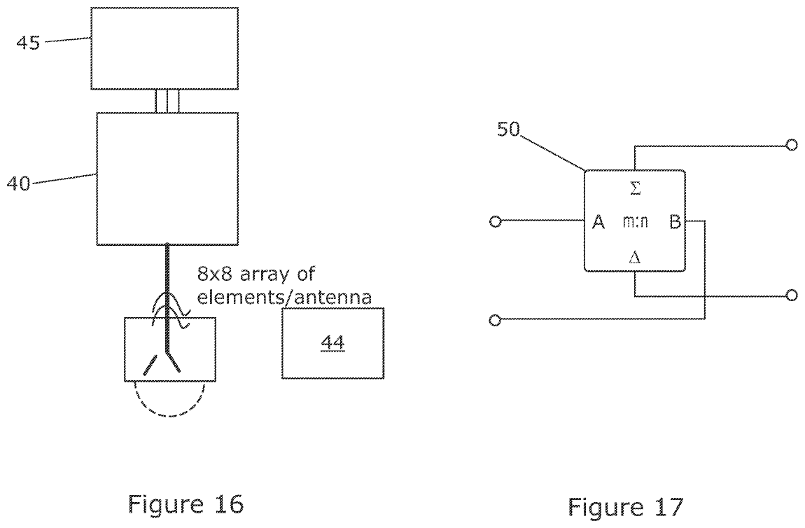

FIG. 16 shows how the fan out phase multiplication circuit of FIG. 4 may provide a feed to a two dimensional array of 64 antenna;

FIG. 17 is a representation of a generic four port bi-directional coupler with a power ratio m:n;

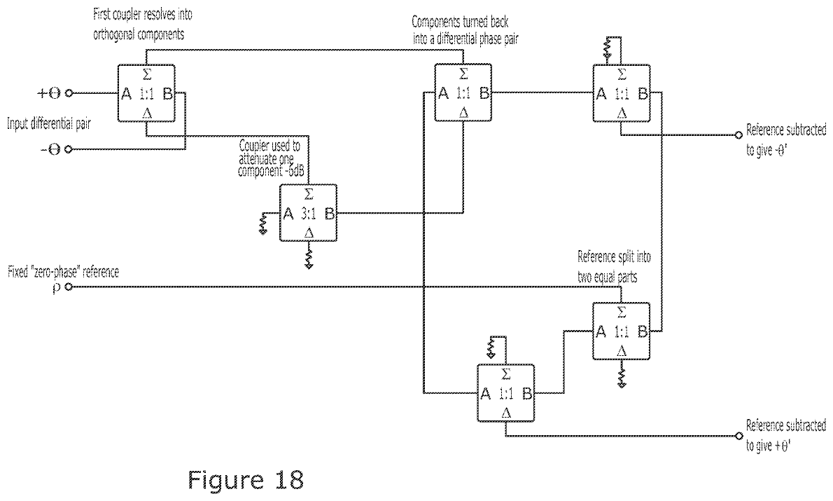

FIG. 18 shows a network of directional couplers arranged according to a first network configuration;

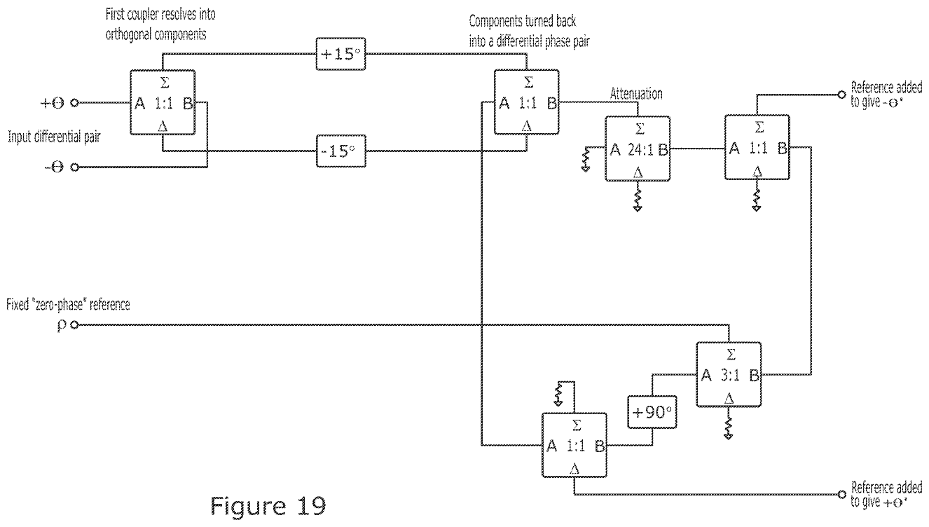

FIG. 19 shows a network of directional couplers arranged according to a second network configuration; and

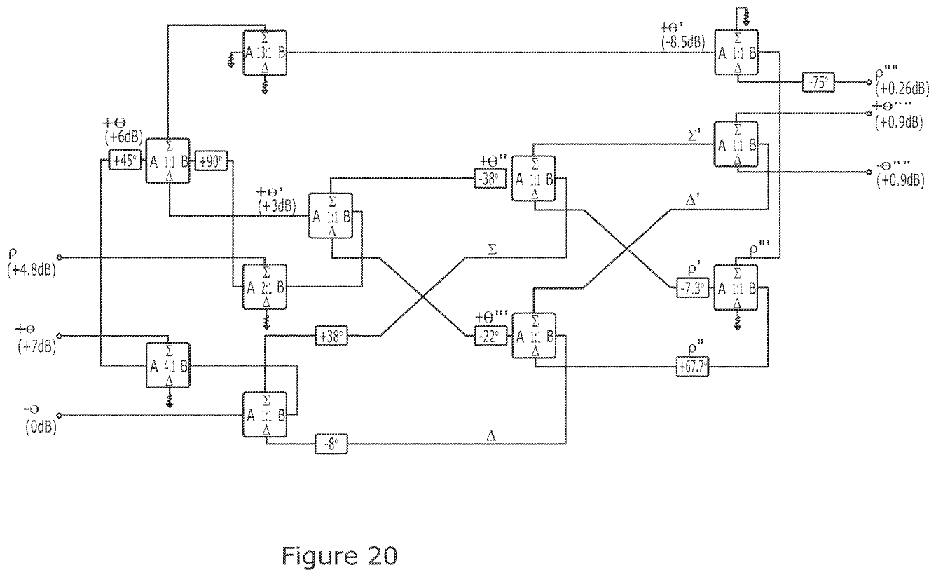

FIG. 20 shows a network of directional couplers arranged according to a third network configuration;

FIG. 1 is an example schematic of a single stage circuit for providing a phase offset which forms a building block for a phase multiplication circuit in accordance with an aspect of the invention.

The phase multiplication circuit 1 comprises a phase multiplier 2 including a passive network of linear directional couplers. Examples of such couplers in the field of microwave/millimetre wave electromagnetics include: Rat-Race or branch-line coupler, Lange couplers and Magic Tee coupler (waveguide). Lesser known are examples of directional couplers which operate in the acoustic domain, via ultrasonic waveguides for gaseous or liquid media. The figures and examples described are equally applicable to both electromagnetic and acoustic domains The invention is not limited to any one of these coupler types. The figure shows an ideal (no transmission line/waveguide losses) single stage circuit having +0.33 θ phase shift (×1.33 phase gain).

Each functional component in the phase multiplier 2 may be formed using a four-port bi-directional coupler, such as a rat-race coupler. The coupler may include two input coupler ports that receive a pair of opposite phase signals and provide, at output coupler ports, the real and imaginary signals which respectively comprise a vector sum of the two received signals and a vector difference of the two received signals, the two resolved output signals being fed to the phase multiplication circuit.

The input to the passive network of linear directional couplers of the phase multiplier are the orthogonal components derived from the differential part of signals +θ, −θ, and ρ. The output signals are +θ″″, −θ′′ and ρ′′ and each have a phase shift proportional to θ (e.g., +0.33 θ). An input stage 3 made up of a pair of active phase shifters supplies these signals to the phase multiplier 2.

The phase multiplication circuit 1 can be implemented in a variety of ways, each using only directional couplers and a few resistive elements and will be explained later, a specific preferred example for the phase multiplication circuit of FIG. 1 being illustrated in FIG. 20 and described at the end of this description.

FIG. 2 is an example schematic of a developed phase multiplication circuit 20 in accordance with an aspect of the invention which gives higher levels of multiplication than are achieved in that of FIG. 1. The developed circuit is formed by cascading three of the phase multiplication circuits 2 of FIG. 1 in three sequential stages. The developed circuit therefore has 3 phase multipliers (each considered to be a sub-circuit of the developed phase multiplier) with the overall phase shift being the sum of the phase shifts of each phase multiplier. The developed circuit is again entirely passive and made up only of four-port couplers, resistors, and interconnects. With appropriate attention given to power proportions, three such stages would achieve +1.0 θ phase shift (i.e., ×2.0 phase gain), as depicted in FIG. 2 (with power balancing omitted). These three cascaded phase multiplication circuits may together still be considered to be a phase multiplication circuit within the scope of the first aspect of the invention.

FIG. 3 is a further schematic of an example more developed phase multiplication circuit 30 which is configured to provide a three phase to eight phase configuration. This uses six of the developed phase multiplication circuits 20 of FIG. 2 to form three stages that fan-out so that the same 2 θ difference seen at the input is distributed across multiple adjacent outputs Each stage of this fan contains 12 sub-stages (similar to FIG. 2 with three sub-stages) to achieve +2× θ phase shift. The more developed circuit therefore has 18 phase multipliers. It is shown that both positive and negative phase shifting can be utilised to implement a balanced tree structure, here shown for 3 inputs cascading to 8 outputs. Power balancing is omitted, but can be assumed prior to each stage and at each branching point, using the methods discussed above.

FIG. 4 shows how a phase multiplication circuit of the type shown in FIGS. 1 to 3 can be used to provide a set of output signals suitable for feeding the antenna or acoustic elements of a two-dimensional phased array. A plurality of cascaded phase multiplication circuits are connected in two layers to form a complex phase multiplication circuit 40. The first layer 41 comprises three phase multiplication circuits each represented by a block 30 where each block 30 is the more developed phase multiplication circuit of FIG. 3 so has three inputs and eight outputs. Each block will therefore itself contain 36 phase multipliers, 12× FIG. 2, where FIG. 2 depicts 3× phase multipliers which each receive signals at their input ports from a separate pair of active phase shifters (not shown). Each of the active phase shifters receiving an input signal from a source and generates the signals +θ and −θ can be derived using two phase shifters acting on the 0° reference. The 2D case requires 8 signals as a function of both θ and ϕ.

The second layer 42 comprises a further eight blocks, each block also comprising a three input eight output developed phase multiplication circuit 30 as shown in FIG. 3. The signals output at the output ports of the first layer are connected to the input ports of the second layer. The two layers are connected such that each block in the second layer receives one signal from each block in the first layer. The output ports of the cascaded phase multiplication circuits in the second layer by each feed an antenna or acoustic element arranged in a 2D grid. In this arrangement there are a total of eight blocks in the second layer 42, and a total of 288 phase multipliers are used.

FIG. 16 shows the outputs from the more developed phase multiplication circuit 40 of FIG. 4 feeding into a set of 64 antennas of an antenna array to form an assembly according to the second aspect of the invention. The phase multiplication circuit 40 is fed with two out of phase signals and a fixed reference zero degrees signal generated by a few active phase shifters represented by the upper block 45 in the diagram.

Using a phase multiplication circuit according to an aspect of the invention, a continuous, smoothly steered output signal could be achieved for a simple 8×8 2D array at the cost of only eight (high-resolution) active phase-shifters (the required passive circuitry being implemented as a copper pattern in the printed circuit). Cost is then determined principally by the area of PCB material required, not by the intricacy of the copper pattern produced. To contrast, in a conventional 8*8 array there would need to be 64 active phase shifters, a significant increase.

To understand how the circuit of FIGS. 1 to 4 can be implemented in practice and how the network of couplers achieves a phase multiplication first consider how a Directional Coupler works, by which we mean a linear, passive bi-directional device which may itself be implemented via transmission lines or waveguides. By appropriate choice of device, the circuit may be operable in any of a range of different frequency bands including electromagnetic or acoustic domains.

A directional coupler is most commonly utilised as a means for achieving power splitting or power combining of in-phase signals. An ideal 3 dB hybrid coupler is a particular instance which provides, for example, equal splitting of an input signal such that the two outputs are of equal magnitude and at half the power of the input. When used as a power combiner, any slight difference in magnitude or phase of the two inputs directs a (usually small) proportion of power to the isolated port, where it is most-commonly dissipated in a non-reactive (resistive) terminating load.

A directional coupler can be regarded as a bi-directional passive four-port coupler capable of performing analogue vector sum and difference operations. A generalised view of an exemplary one dimensional bi-directional four-port coupler 50 is shown in FIG. 17.

In general, for voltage (or current) signals A and B entering (or leaving) a directional coupler designed with power combining (or splitting) ratio of m:n, the two other ports Σ and Δ may be considered as “vector sum” and “vector difference” respectively, where:

$$Σ = A \sqrt{\frac{m}{m + n}} + B \sqrt{\frac{n}{m + n}}$$

$$and :$$

$$Δ = A \sqrt{\frac{n}{m + n}} - B \sqrt{\frac{m}{m + n}}$$

For the case where m=n, equal split/combine, 3 dB coupling, this simplifies to:

$$Σ = A \sqrt{\frac{1}{2}} + B \sqrt{\frac{1}{2}}$$

$$and :$$

$$Δ = A \sqrt{\frac{1}{2}} - B \sqrt{\frac{1}{2}}$$

Which, for an ideal coupler, can easily be shown to satisfy power conservation laws. For the case where n>>m (or vice-versa), this results in negligible coupling where (at the limit):

$$Σ = A , \qquad Δ = - B$$

$$or :$$

$$Σ = B , \qquad Δ = A$$

In the circuit of FIG. 1, an alternative property of a linear passive directional coupler is exploited, namely that it can be used to resolve angles. For independent vector θ, having arbitrary fixed magnitude and variable phase confined to a single quadrant (e.g., 0-90° sweep range), applying +θ and −θ as inputs to the two ports A and B of a single directional four port coupler results in Σ and Δ as fixed phase, variable magnitude component vectors of θ aligned with orthogonal axes. This is shown in the Nyquist plot of FIG. 5 (shown with θ varying from 5° to 85° for clarity, circles and arrowheads denote start and end values respectively.

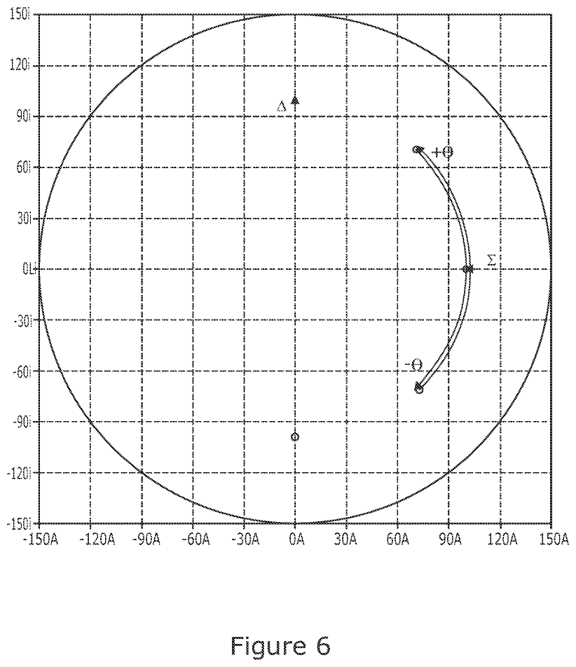

FIG. 6 shows a similar case to FIG. 5, but with θ instead varying from −45° to +45° (for clarity, +θ is shown magnified by 2%), achievable by applying a fixed phase lag of 45° to +θ and fixed 45° phase lead to −θ (fixed phase shifts are achievable through well documented techniques, some trivial). Now, Σ starts at 70.7%, rises to 100% as +θ and −θ cross at 0°, then falls back to 70.7% along the real axis. Δ starts at −70.7%, moves towards zero along the imaginary axis as the differential input phases cross, and ends at +70.7%. Note that the traces are still circular in FIG. 6.

The networking of the directional couplers can be done using one of three different configurations which achieve the require phase multiplication. These three different network configurations can be combined with a single phase multiplication circuit.

### First Network Configuration—Attenuation of Axial Component.

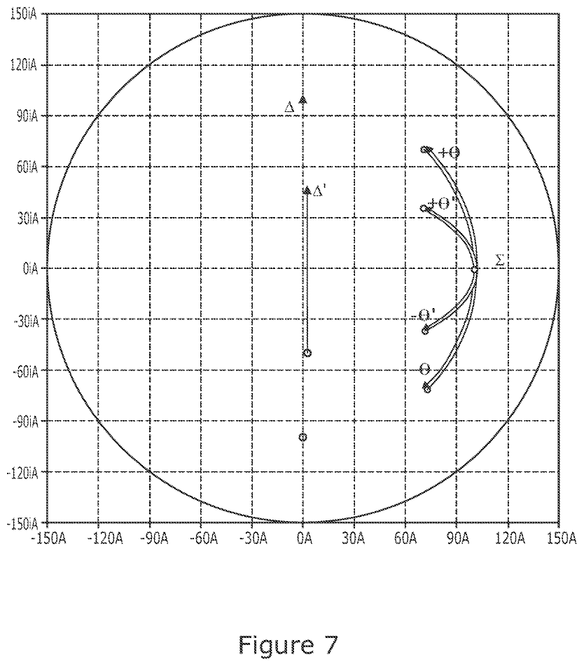

Because directional couplers are reciprocal, Σ and Δ can be fed into a second coupler to reproduce +θ and −θ. If, however, the Δ current/voltage signal is attenuated to give Δ′, e.g., by half (−6 dB power attenuation), then the outputs +θ′ and −θ′ of such a two-stage cascade circuit follows an elliptical trajectory, as shown in the plot of FIG. 7 (minor magnifications and Δ′ offset for clarity). An unequal-split directional coupler would be one suitable means to provide this attenuation.

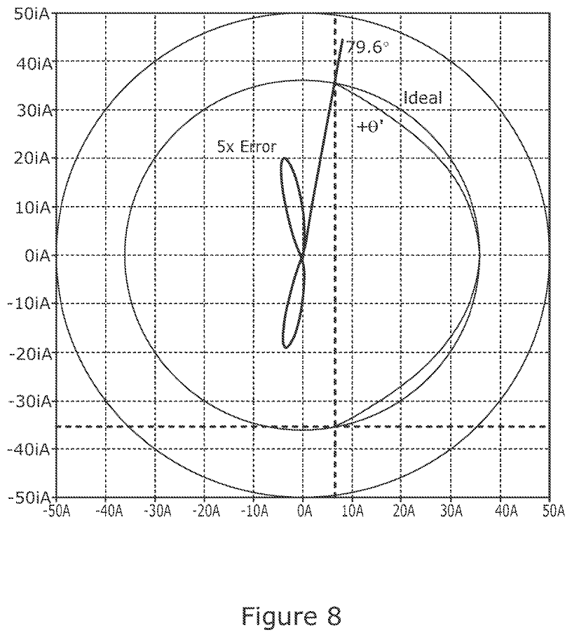

Finally, a fixed phase offset may be subtracted (using further directional couplers and additional 0° phase input signal) from outputs +θ′ and −θ′, such that they again approximate a circular trajectory. FIG. 8 shows this for +θ′ only, resulting (in this instance) with almost 160° of phase output swing, for 90° (−45° to +45°) of +θ input swing. An ideal circular trajectory is shown in the figure as a reference.

The output trajectory is seen to match the ideal phase and magnitude at three points, with a maximum magnitude error of approximately 11.3% (−1 dB power) and a few degrees maximum phase error. However, this approach has several drawbacks:
The output signal θ′ has only a small magnitude compared with θ. This example shows an idealised magnitude of 36%, or almost 9 dB power attenuation (87% power loss)—which would rapidly diminish the signal after a few cascaded stages.
Both +θ′ and −θ′ have the same phase magnification, so their maximum difference is also +/−160° and no-longer confined to a single quadrant. The outputs as shown are therefore unsuitable for cascading into a similar second stage.
The offset subtraction described here can be achieved with a 3 dB coupler, but the signal (as expected) would suffer a further 3 dB attenuation. With θ′ as A and the offset as B input, only the Δ (difference) output is useful. This further loss may be minimised to almost zero, but at the expense of requiring a high m:n power combining ratio and large offset input power far exceeding the actual offset achieved.

FIG. 18 is a circuit diagram of a network of directional couplers that embodies the first network configuration and may be used in the circuit of FIG. 1 as the phase multiplication circuit. The input can be seen at the top left, and outputs two orthogonal components. One of those is attenuated and the two are then turned back into a differential pair using a directional coupler. Three further couplers are then used to subtract a zero degrees reference phase signal such that the two output signals approximate a circular trajectory.

### Second Configuration—Skew of Axial Components

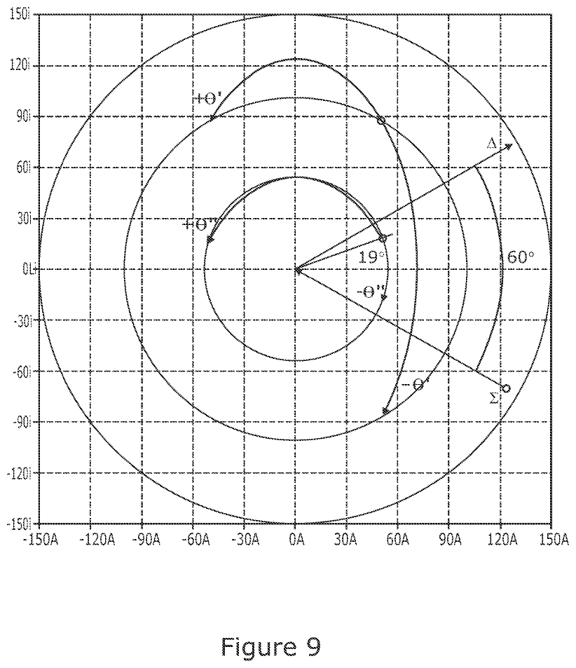

Rather than attenuating one orthogonal component (A) of the resolved phase θ, the angle between Σ and Δ can be skewed away from 90° before feeding into the second coupler, with the effects shown in FIG. 9.

For input phases +θ and −θ (as depicted in FIG. 5, each sweeping through 90°—not shown here), reducing the angle between Σ and Δ to 60°, for example, results in elliptical trajectories for +θ′ and −θ′. Now +θ′ and −θ′ sit in adjacent quadrants of the ellipse, having differing curvature. +θ′ can have an offset subtracted along the imaginary axis (as shown) to become a 3-point fit to a new circular trajectory +θ″. −θ′ requires attenuation (here approximately to one-fifth magnitude) before having offset added along the real axis to become −θ″, being a good match to the same circular trajectory as +θ″.

Now, for this particular skew, it can be seen that +θ″ has a sweep range of approximately 142°, whereas −θ″ has a sweep range of 38° in the negative sense, both seeing a linear phase shift of +52° (for θ having 90° sweep) or, more generally: a 0.58×θ common phase shift, or 1.58×θ (for +θ″) and 0.42×θ (for −θ″) phase multiplication. The difference angle between +θ″ and −θ″ now matches that for +θ and −θ throughout the sweep (with small phase errors as before), making this approach more suitable for cascading. In addition, the θ″ signal magnitude is greater, here approximately 53% for a broadly similar phase gain as the example used in the first approach, reducing the overall power loss to approximately −5.5 dB—a worthwhile improvement.

FIG. 19 is a circuit diagram of a network of directional couplers that embodies the second network configuration and may be used in the circuit of FIG. 1 as the phase multiplication circuit. Again, an input stage can be seen top left in the form of a linear passive directional coupler. This feeds two orthogonal components through respective fixed phase shifters of 15 degrees and −15 degrees and these signals are turned back into a differential phase pair by a further linear passive directional coupler. Further couplers take the two differential signals and combine with a zero-phase reference signal to form the output signals which have a common phase shift of +0.58 θ. Hence one output signal has phase gain of ×1.58, the other ×0.42.

### Third Configuration—Rotation of Axial Components

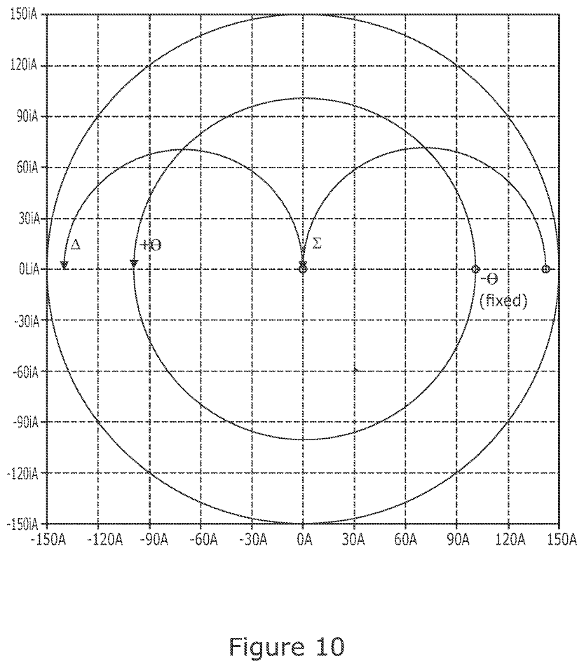

In a further alternative configuration of directional couplers within the scope of an aspect of the invention and used in the circuit shown in FIGS. 1 to 4, consider that a useful unit of phase shift would be 90°, or 2×θ phase multiplication. Here, +θ′ would sweep through 180° and −θ′ would remain at fixed phase. FIG. 10 synthesises this case for Σ and Δ by having +θ and −θ sweep through 180° and 0° respectively. With comparison to FIG. 5, Σ and Δ both start with full magnitude along the real axis and zero magnitude at the origin, respectively. FIG. 10 can be understood as a +90° rotation of these axial components, as their magnitudes fall and rise respectively, such that Σ is asymptotic to the imaginary axis as it arrives at the origin, and Δ ends at full magnitude on the negative real axis.

As can be seen by inspection, the axial components required to synthesise a 180° sweep are themselves 180° semi-circular trajectories—an apparently unresolvable dependency. However, by choosing a lesser amount of phase gain, a good match to the required Σ and Δ components can be derived from +θ, −θ and a fixed offset signal. One such case for a phase gain of 1.33×θ (+30° linear phase shift) is described as follows.

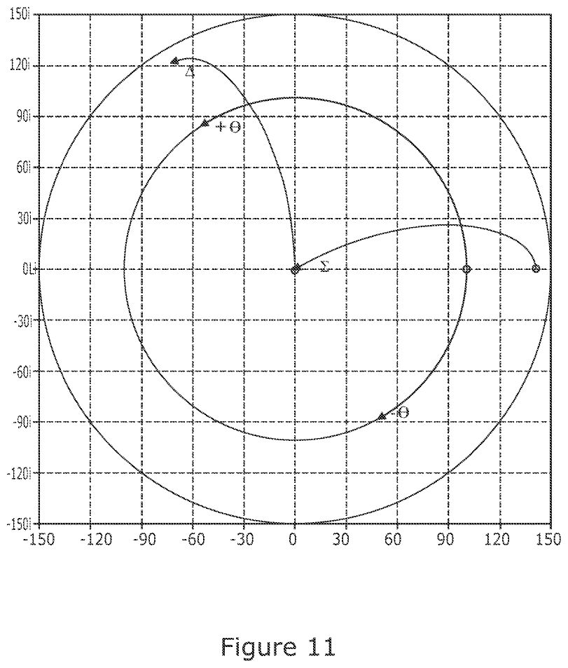

FIG. 11 is similar to FIG. 10, showing ideal Σ and Δ components synthesised from ideal +θ and −θ inputs sweeping 0° to 120° and 0° to −60° respectively (i.e., both shifted by +30° as the sweeps complete).

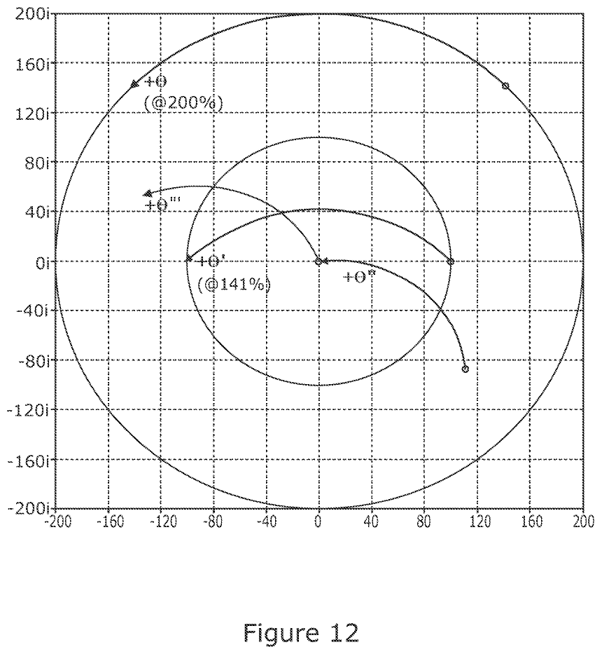

FIG. 12 begins the process of approximating this ideal Σ and Δ by starting with an additional (larger)+θ input having 45° to 135° sweep (0° to 90° sweep with trivial +45° fixed phase shift) and subtracting a fixed-phase offset along the imaginary axis using a 3 dB coupler to bring +θ′ down to touch the real axis. As discussed previously, this 3 dB drop in +θ′ signal may be avoided by using an unequal-split coupler, at the expense of requiring a larger offset signal. +θ′ then enters another 3 dB coupler with a real-axis offset, to produce both sum and difference signals +θ″ and +θ″′, shown with additional fixed phase shifts applied.

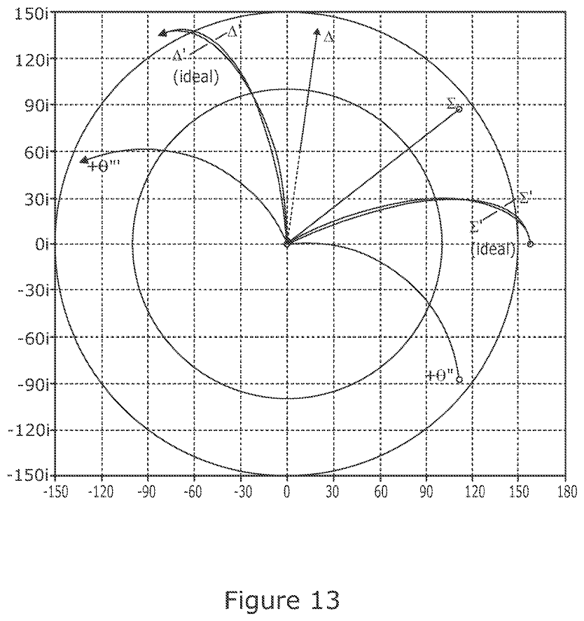

FIG. 13 show the second stage of approximation, where +θ″ is summed with Σ, which is produced as for FIG. 5 (with fixed phase shift) and +θ″′ is summed with Δ, also as FIG. 5 (again with fixed phase shift). It is evident that the resultant Σ′ and Δ′ are good approximations for the ideal Σ′ and Δ′, when the latter are magnified by 111%.

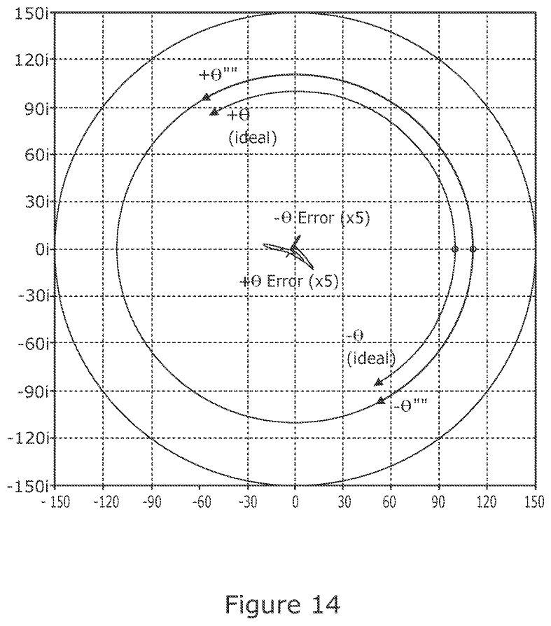

FIG. 14 shows the final +θ″″ (1.33 phase gain) and −θ′′ (−0.67 phase gain) signals, together with the ideal case. Also shown is the error between synthesised and magnified (111%) ideal signals, magnified 5 times. Note how this error is much smaller in relative terms compared to the approach depicted in FIG. 8.

The description above would be incomplete without consideration of cascading requirements.

Firstly, the differential input pair +θ and −θ, when centred at mid-sweep, have a phase difference extending from −90° to +90° (i.e., independent variable θ is confined to one quadrant)—this property must be present at the differential output pair, which is the case for the second and third approaches described above.

Secondly, the frequent mentions of “fixed-phase offset subtraction” assume, of-course, the availability of such a signal—which would appear straightforward in the initial case. However, this fixed-phase signal cannot be simply passed through to subsequent cascaded stages because the average phase of +θ″″ and −θ″″ outputs is no-longer fixed. In the case shown in FIGS. 8 to 10, a mid-point reference, ρ″″, is required which sweeps from 0° (when +θ″″ and −θ″″ are both zero) to +30° (when +θ″″ is 120° and −θ″″ is −60°).

Thirdly, the ideal case would be for the three input signals, +θ, −θ and ρ, to be available in the same power proportions (with minimised losses) after phase gain has been applied, to produce outputs +θ″″, −θ″″ and ρ″″. In the non-ideal case, the required output signal proportions may be realised by:
Over-supply of input signal power, such that the required output power is achieved for the greater of +θ″″, −θ″″ and ρ″″. Excess power in the remaining signals may then be attenuated and resistively dissipated.
Power recuperation of rejected signals. This may be achieved, for example, by recombination of “waste” signals to match the trajectory of any input or output signal, subtracting from the input power requirement or supplementing the output power of a stage. Another means would be to send these “waste” signals for rectification, reducing the dc power requirement for the entire apparatus.
Amplification of attenuated signals using a fixed gain (or acoustic) device. Note, this still will mean the phase multiplier is no longer completely passive but the small amount of active circuitry needed will reduce costs compared to the provision of additional active phase shifting or variable gain amplification as in the prior art, for example U.S. Ser. No. 10/897,082B1.

FIG. 13 depicts rotating axial component approximations, Σ′ and Δ′, generated by summing +θ″ with Σ and +θ″′ with Δ, respectively, via 3 dB couplers. The previously unused difference outputs, ρ′ and ρ″, respectively, may be combined to produce phase trajectories, ρ″, across a range of angular sweep (180° sweep limit) in both positive and negative directions, but with magnitude dipping between start and end angles.

Similarly, the first offset subtraction shown in FIG. 12 also produces a large signal with offset added (also now designated +θ′ for convenience), where the trajectory has rising magnitude between start and end.

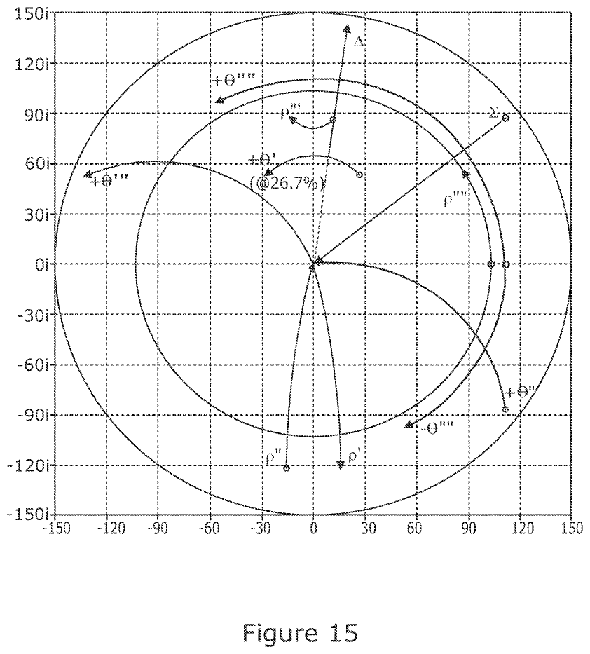

FIG. 15 shows how, by choosing appropriate axial component skew (the fixed angle between ρ′ and ρ″) and attenuation of +θ′, these two “waste” signals, ρ″′ and +θ′, may be combined to generate the required mid-point reference output, ρ″″, having near-circular trajectory (i.e. minimal magnitude dip or rise) and correct sweep range (30° in this case)—without need for a variable gain (or variable attenuation) controlled device.

FIG. 20 shows a circuit which embodies this third network configuration. It is modelled as an ideal (no transmission line/waveguide losses) single stage circuit having +0.33 θ phase shift (×1.33 phase gain). The relative power amplitudes of the input signals +θ, −θ, and ρ, and of the output signals +θ″″, −θ′′ and ρ′′ are annotated in dB, with positive fixed phase shift values representing phase lead. “Waste” signals are shown dissipated via matched resistive loads. The signals +θ″″, −θ″″ and ρ″″′ are each shifted by +0.33 θ compared to the associated input signals.

1. A phase multiplication circuit comprising:
a phase multiplier comprising a network of linear passive directional couplers acting on a phase difference between a differential signal pair, +θ and −θ, together with a third signal, ρ, which is the average phase of the differential pair and outputting one or more signals with magnitude proportional to the input signals and with a phase shift proportional to an input phase difference.

2. A phase multiplication circuit according to claim 1 in which the network of passive components is configured to perform linear vector arithmetic on the signals that includes at least one of the following steps;
(i) resolving the pair of signals into their real and imaginary components and attenuating either the real or imaginary or both of the real and imaginary axial signal components;
(ii) resolving the pair of signals into their real and imaginary components and skewing of either the real or imaginary or both of the axial signal components; and
(iii) rotation of both the real and imaginary axial components of the pair of signals.

3. A phase multiplication circuit according to claim 1 which is operable in the electromagnetic domain.

4. A phase multiplication circuit according to claim 1 which is operable in the acoustic domain.

5. A phase multiplication circuit according to claim 1 which is operable over a narrow or wide frequency band.

6. A phase multiplication circuit of claim 1 in which the phase multiplier circuit outputs at least three signals with magnitudes proportional to the input magnitudes of +θ, −θ and ρ, but with common positive (or negative) phase shift as a multiple of θ.

7. A phase multiplication circuit according to claim 1 which, via reciprocity of its linear, passive components, is able to function in the reverse sense where outputs are swapped for inputs and vice-versa.

8. A phase multiplication circuit of claim 1 which further includes a cascaded arrangement of phase multiplier circuits.

9. A phase multiplication circuit according to claim 1 in which a plurality of phase multiplier circuits are connected in a tree-like network of branches, each branch having a root node and multiple leaf nodes, the phase multipliers in each branch acting on the initial phase difference provided at the input root nodes and distribute this phase difference or multiple thereof across multiple adjacent pairs of leaf nodes.

10. A phased array comprising a circuit according to claim 9, and a set of transmitting or receiving antennas or acoustic elements.

11. A phased array according to claim 10 comprising a linear transmitting or receiving phased array, where the antenna elements (or acoustic transducers) are connected to the “leaf” nodes of the phase multiplication circuit, and either
the transmitting phased array is steered by the phase difference signals provided at the root-node, or
the receiving phased array provides power-combination and received signal direction information via the signals output at the root node.

12. A phased array according to claim 10 comprising a two-dimensional transmitting (or receiving) phased array system where the antenna elements (or acoustic transducers) are connected to the “leaf” nodes of the phase multiplication circuit, having x by y elements, having similar architecture and properties to the linear phased array system, but comprising 3×3 or-more inputs (3×3 or-more outputs) at the “root” nodes connected to a first layer of 3-off (or more) tree-like networks, each with x number of “leaf” nodes, which then connect to a second layer of x number of tree-like networks, each with y number of “leaf” nodes.

13. A phased array according to claim 11 comprising a two-dimensional steerable phased array system of arbitrary size, comprising two-or-more sub-arrays arranged as planar, cylindrical, or other geometry.

14. A method of achieving phase multiplication of a differential pair of signals using a network of passive components, the method comprising:
feeding the pair of signals into a network of passive components together with a zero-degree reference signal. the network configured to perform linear vector arithmetic on the signals that includes at least one of the following steps
(i) resolving the pair of signals into their real and imaginary components and attenuating one of the following: either the real axial signal component, the Or imaginary axial signal component, and er-both of the real and the imaginary axial signal components;
(ii) resolving the pair of signals into their real and imaginary components and skewing of either the real or imaginary or both of the axial signal components; and
(iii) rotation of both the axial components of the pair of signals.

15. A phased array according to claim 12 comprising a two-dimensional steerable phased array system of arbitrary size, comprising two-or-more sub-arrays arranged as planar, cylindrical, or other geometry.
